(19) United States
(12) Patent Application Publication
(10) Pub. No.: US 2005/0013181 A1
(43) Pub. Date: Jan. 20, 2005

(54) Assisted memory device with integrated cache

(76) Inventors: Todd C. Adelmann, Boise, ID (US); Stewart R. Wyatt, Boise, ID (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/621,632

(22) Filed: Jul. 17, 2003

(51) Int. Cl. G11C 7/00

(52) U.S. Cl. 365/200

(57) ABSTRACT

Disclosed herein are assisted memory devices having an integrated cache and methods implemented therein. In one embodiment, an integrated circuit device comprises a memory array integrated on a substrate with a decoder and a cache also integrated on the same substrate. The decoder may be configured to decode data retrieved from the memory array. The cache may be configured to retrieve data stored in the memory array in anticipation of a request for the data.

### BACKGROUND

Information is extremely valuable for modern development and progress, especially in the development of new technology. However, many ways of storing and preserving information do not allow easy access to it. For example, information may be stored in library books, but identifying and obtaining the correct book often requires significant effort. Costs associated with accessing stored information may reduce the effective value of the information.

Many developing technologies have been embraced because they increase accessibility to information. Microfilm, magnetic tapes, magnetic disk media, optical disk media, and non-volatile integrated memories are examples of technologies that have increased accessibility to information stored on them. Non-volatile integrated memories are of particular interest here.

Integrated memories are electrical circuits that are configured to store information in digital form. This digital information, or “data,” is readily accessible to a digital device appropriately coupled to the integrated memory. Depending on the particular technology employed, data can be accessed at truly astonishing rates.

Integrated memories are often classified as volatile or non-volatile. Volatile integrated memories suffer loss of stored data in the absence of electrical power, but this shortcoming may be offset by advantages in information density and access rates. Non-volatile memories retain their stored information in the absence of electrical power, but may suffer from a reduced information density and a reduced access rate.

A new integrated memory technology offers both non-volatility, high information density, and an improved access rate. Magnetic integrated memories, as that term is used herein, are integrated memories that use magnetic fields to store data, such as those in Magnetic Random Access Memory (MRAM). These magnetic fields can be embedded in magnetic materials that do not rely on the continued presence of electrical power to preserve the magnetic fields. A variety of sensing techniques may be employed to detect magnetic fields in these memories and to determine the data these fields represent.

Although some improvement may be achieved, the access rates offered by magnetic integrated memories may still fall short of the access rates offered by volatile memory technologies. A method for reducing average read times of various memory technologies may prove advantageous.

### BRIEF SUMMARY

Accordingly, disclosed herein are assisted memory devices having an integrated cache and methods implemented therein. In one embodiment, an integrated circuit device comprises a memory array integrated on a substrate with a decoder and a cache also integrated on the same substrate. The decoder may be configured to decode data retrieved from the memory array. The cache may be configured to retrieve data stored in the memory array in anticipation of a request for the data.

### BRIEF DESCRIPTION OF THE DRAWINGS

For a detailed description of exemplary embodiments, reference will now be made to the accompanying drawings in which:

FIG. 1 shows a computer system in which certain embodiments may be employed;

FIG. 2 shows an integrated memory device;

FIG. 3 shows an integrated memory device with a read cache in accordance with certain embodiments;

FIG. 4 shows an integrated memory device with read and write caches in accordance with certain embodiments;

FIG. 5 shows an integrated memory device in accordance with certain low-powered embodiments; and

FIG. 6 shows a method flow diagram in accordance with certain embodiments.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION

The drawings and following discussion are directed to various embodiments. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to suggest that the scope of the disclosure, including the claims, is limited to that embodiment.

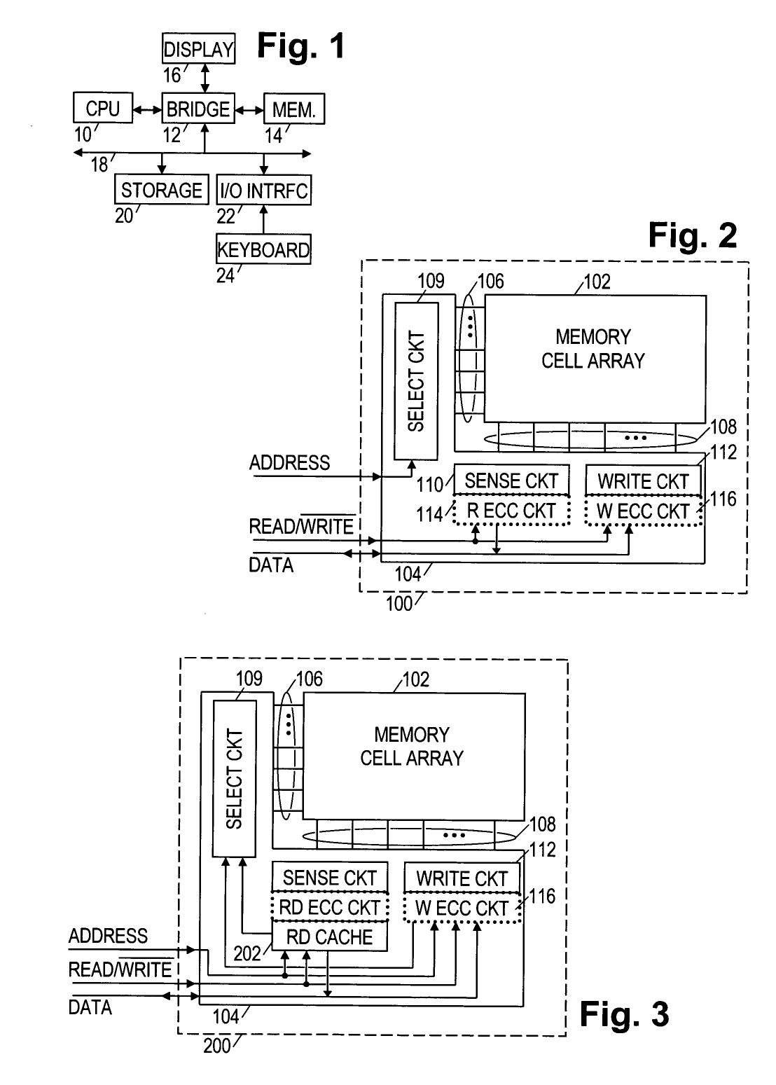

FIG. 1 shows a computer system, which is but one example of where an integrated memory may be employed. The computer system of FIG. 1 includes a central processing unit (CPU) 10 coupled by a bridge 12 to a system memory 14 and a display 16. CPU 10 is further coupled by bridge 12 to an expansion bus 18. Also coupled to the expansion bus 18 are a storage device 20 and an input/output interface 22. A keyboard 24 may be coupled to the computer via input/output interface 22.

CPU 10 may operate in accordance with software stored in memory 14 and/or storage device 20. Under the direction of the software, the CPU 10 may accept commands from an operator via keyboard 24 or some alternative input device, and may display desired information to the operator via display 16 or some alternative output device. CPU 10 may control the operations of other system components to retrieve, transfer, and store data.

Bridge 12 coordinates the flow of data between components. Bridge 12 may provide dedicated, high-bandwidth, point-to-point buses for CPU 10, memory 14, and display 16.

Memory 14 may store software and data for rapid access. Memory 14 may be an integrated memory in accordance with various embodiments described below.

Display 16 may provide data for use by an operator. Display 16 may further provide graphics and may include advanced graphics processing capabilities.

Expansion bus 18 may support communications between bridge 12 and multiple other computer components. Bus 18 may couple to removable modular components and/or components integrated onto a circuit board with bridge 12 (e.g., audio cards, network interfaces, data acquisition modules, modems).

Storage device 20 may store software and data for long-term preservation. Storage device 20 may be portable, or may accept removable media, or may be an installed component, or may be a integrated component on the circuit board. Storage device 20 may be an integrated memory device in accordance with various embodiments described below. Alternatively, storage device 20 may be a nonvolatile integrated memory, a magnetic media storage device, an optical media storage device, or some other form of long-term information storage.

Input/output interface 22 may support communications with legacy components and devices not requiring a high-bandwidth connection. Input/output interface 22 may further include a real-time clock and may support communications with scan chains for low-level testing of the system.

Keyboard 24 may provide data in response to operator actuation. Other input devices (e.g., pointing devices, buttons, sensors) may also be coupled to input/output interface 22 to provide data in response to operator actuation. Output devices (e.g., parallel ports, serial ports, printers, speakers, lights) may also be coupled to input/output interface 22 to communicate information to the operator.

In addition to the above-described system, many other general purpose and customized digital devices and systems may beneficially employ integrated memories in accordance with various embodiments such as those described below.

FIG. 2 shows a baseline architecture for an integrated memory device 100. Memory 100 includes a memory cell array 102 and support circuitry 104. Memory cell array 102, as the name suggests, is an array of memory cells. Each memory cell can store a data value (e.g., a bit), and each cell may be identified by its position (e.g., by row and column coordinate). The memory cells can be implemented using any suitable technology including magnetic random access memory (MRAM).

Support circuitry 104 may receive an address signal, a read/write signal, and a data signal. The address signal may represent an address value as a binary number. Each address value may be associated with a set of one or more cells in the memory array. For example, each cell may be associated with a unique address value. As an alternative example, each address value may be associated with a corresponding ordered set of 64 cells.

The read/write signal may be a signal with at least two values, one value being the “asserted” state, and the other value being the “de-asserted” state. In the asserted state, the read/write signal may cause a read operation to occur, in which data from the memory cell array 102 is retrieved. In the de-asserted state, the read/write signal may cause a write operation to occur, in which data is provided for storage in the memory cell array.

The data signal may represent a data value as a binary number. The data signal may be bidirectional so that it may be received by the support circuitry 104 during a write operation, and may be provided by the support circuitry 104 during a read operation. Although the address, read/write, and data signals are shown separately, they may be multiplexed with each other and/or multiplexed with other signals.

Support circuitry 104 may be coupled to memory cell array 102 by row lines 106 and column lines 108. Support circuitry 104 may include various subcircuits which cooperate to carry out read and write operations on the memory cell array. The subcircuits may include a selection circuit 109, a sense circuit 110, a write circuit 112, and optional error correction code (ECC) decoder and encoder circuits 114, 116.

Selection circuit 109 may convert the address signal into a corresponding pattern of assertions and de-assertions that make the addressed memory cell(s) accessible to the sense circuit 110 and/or write circuit 112. Depending on the memory cell architecture, the selection circuit may apply the pattern of assertions and deassertions to row lines 106 and/or column lines 108. Alternatively, the pattern may be applied to gates and/or multiplexers that couple the appropriate row lines 106 and/or column lines 108 to the sense circuit 110 and/or write circuit 112. The memory cell(s) associated with an address may in some architectures be made accessible in parallel, and in other architectures may be made accessible sequentially. Many suitable memory cell array architectures and selection circuits are known to those of skill in the art and may be used.

As selection circuit 109 makes the addressed memory cell(s) accessible for a read operation, sense circuit 110 may detect some electrical characteristic of the addressed memory cell(s) that is indicative of corresponding data value(s) stored therein. The sensing technique used may depend on the memory cell architecture, and a great variety of suitable sensing techniques are known to those of skill in the art. Generally, however, a typical sense circuit 110 may detect a voltage, a current, a resistance, or some related quantity (e.g., rates of change, ratios, differences). Sense circuit 110 may compare the measured quantities to one or more reference values and thereby produce a digital representation of the stored data value(s).

As selection circuit 109 makes the addressed memory cell(s) accessible for a write operation, write circuit 112 may orient one or more magnetic fields in the addressed memory cell(s) so as to represent stored data value(s). The write technique may depend on the memory cell architecture, and a number of suitable writing techniques are known to those of skill in the art. Generally, a typical write circuit 112 may apply a representative voltage or current in a fashion that sets the desired electrical characteristic to represent the data value(s) to be stored.

It is generally regarded as desirable to minimize the probability of a read or write error in memory device 100. If the memory cell architecture fails to inherently provide a sufficiently low probability of error, the probability of error may be further reduced by use of an error correction code (ECC). To this end, support circuitry 104 may further include an ECC encoder 116. As part of a write operation, ECC encoder 116 may process the data signal value(s) to determine a code word that is stored in the addressed memory cells. In general, the code word contains the data value(s) and in addition contains redundant information to enable the detection and correction of errors. As part of a read operation, the sense circuit 110 detects the stored code word, possibly with one or more errors. ECC decoder 114 may process the digital output of sense circuit 110 to extract the stored data values, even in the presence of a limited number of errors.

A wide variety of suitable ECC techniques are known to those of skill in the art. A particularly popular ECC family which may lend itself to this application is the Reed-Solomon family of ECCs, but other ECCs would also serve well. Although technically not ECCs, error detection codes may be similarly used. Though these codes do not reduce error probabilities, they do allow for the detection of errors so that external measures may be taken to handle the error occurrence.

Other types of encoders/decoders may also be used. For example, the digital values may be stored in encrypted form, so that the stored information can only be retrieved via the support circuitry, and even then only by the possessor of the appropriate decryption key. In this circumstance, encoder 116 may be an encryption circuit, and decoder 114 may be a decryption circuit.

FIG. 3 shows an architecture for a memory device 200 with an integrated cache 202. The integrated cache 202 may operate as a predictive cache to provide improved read performance. Notably, such improved performance may be attained without any intervention or management from a host computer or microprocessor.

A cache is a relatively high-speed memory that stores data values from memory locations that are imminently likely to be accessed. By maximizing the probability that needed memory location data values are in a faster memory, the average memory access time may be reduced, thus allowing computers to operate more quickly.

Various caching techniques may be employed by integrated cache 202. In one technique, cache 202 may obtain (and retain) data values from memory locations near each memory location that is accessed. In one embodiment that incorporates this technique, the memory array 102 may be conceptually divided into memory “blocks”. When a data value is desired from a given location in the memory array 102, cache 202 may obtain all the data values from the memory block that includes the given memory location. In an alternative embodiment that incorporates this technique, cache 202 obtains data values from a number of memory locations subsequent to each accessed memory location.

In a second caching technique, cache 202 relies on pattern analysis and/or statistical analysis to predict the next memory location to be accessed, and to anticipate that access by placing the memory location data value in the cache. Certain variations of this technique may determine multiple predictions between accesses and may load the data values from each of the predicted memory locations into the cache. To aid in making these predictions, additional statistics-gathering fields may be allocated in the memory cell array.

A third caching technique may be a hybrid variation of the first two caching techniques. In one specific example, the memory array is conceptually partitioned into memory “blocks”, e.g., blocks of 512 bytes. Whenever a memory location within a block is accessed, the entire block is copied into the cache. Associated with each block may be a statistics gathering field that the cache uses to compile information on which memory block(s) were subsequently or previously accessed. The cache may update the field each time a block is accessed. The information may be stored as a simple Pareto table or some more elaborate form. The cache may also use the statistics-gathering field as a small predictive jump table. For example, when a memory block is accessed, cache 202 may predict the block that will be subsequently accessed, and may initiate retrieval if the block is not already in the cache. If the memory device is non-volatile, the compiled statistics information may be maintained from session to session.

In another specific example of a hybrid caching technique, the statistics gathering may be omitted in favor of a simpler predictive rule. Whenever a memory location within a memory block is accessed, the entire memory block may be copied into the cache. The cache may then predict that the numerically subsequent memory block is likely to be accessed, and may accordingly initiate retrieval if the block is not already in the cache.

Once cache 202 is filled, a procedure is provided for replacing existing entries with new entries. Various replacement approaches may be used, including “first-in first-out” (FIFO) and oldest last-access. In the FIFO approach, the newest entry replaces the oldest entry (after the cache is full). In the oldest last-access approach, a last-access time is associated with each block of values in the cache. Each time the block is accessed, the last-access time is updated. Once the cache is full, the block of values with the oldest (earliest) last-access time is replaced with the new entries.

Cache 202 may use any of the described caching techniques, or alternatively may use other suitable caching techniques. If the system in which integrated memory device 200 is embedded employs higher level caching techniques, the technique used by cache 202 may advantageously be designed to complement the other caching operations in the system.

Cache 202 may be a high performance memory such as static random access memory (SRAM). Cache 202 may include a cache controller that receives the address and read/write signals, and that further provides address and enable signals to selection circuit 109. The cache controller may be implemented in hardware or firmware, and the controller may operate to monitor the address and read/write signals to determine (1) whether a requested memory location data value is in the cache memory, (2) which (if any) memory location data value should be retrieved next, and (3) which (if any) memory location data value should be replaced in the cache.

A cache “miss” occurs when cache 202 receives a read operation requesting data from a memory location not stored in the cache. The cache controller may access the memory cell array via selection circuit 109, sense circuit 110, and optional decoder circuit 114 to obtain the requested data. Once the requested data has been received, cache 202 may provide the requested data on the data signal lines and may further store the requested data in cache memory.

A cache “hit” occurs when cache 202 receives a read operation requesting data from a memory location that has been stored in cache memory. Cache 202 may immediately provide the requested data on the data signal lines.

During any respite between cache misses and/or memory write operations, cache 202 may initiate read operations to update the cache memory in accordance with the cache's latest evaluation of which memory locations have a high probability of imminent access. If the memory has multiple ports, or if the memory cell array is partitioned in a manner that allows for concurrent accesses, the cache controller may also conduct cache update operations during cache misses and memory write operations.

Note that in FIG. 3, selection circuit 109 has two address signal inputs: one from read cache 202, and one from write circuit 112 or optional encoder circuit 116. The selection circuit 109 may perform conflict-resolution in a manner that provides priority to write operations. Alternatively, cache 202 may avoid performing access operations when the read/write signal indicates a write operation is in progress.

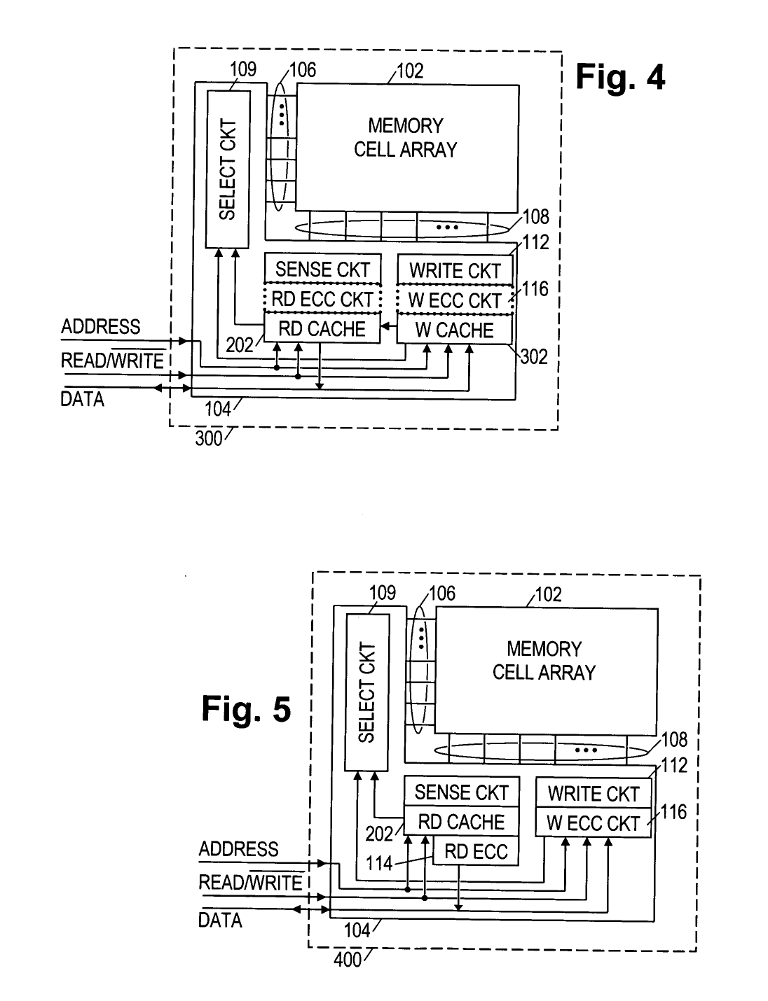

FIG. 4 shows an architecture for a memory device 300 with an integrated read cache 202 and integrated write cache 302. While these caches are shown separately for explanatory purposes, their functionality may also be combined into a single cache unit.

Write cache 302 may accept data values to be written to memory cell array 102. Write cache 302 may operate primarily as a buffer, or alternatively write cache 302 may provide additional caching functionality. As a buffer, write cache 302 may, for example, accept write data at a “burst rate” that is greater than the rate at which the data can be written to the memory cell array. In addition, or alternatively, write cache 302 may operate as a buffer to accumulate some number of write operations to be performed together for speed or power efficiency reasons. (Some memory cell array architectures may be unable to switch between read and write modes without a delay and/or reallocation of power.)

Write cache 302 may also provide even more caching functionality. For example, write cache 302 may delay writes to memory cell locations that are imminently likely to be rewritten, and may further drop useless write operations. (Write operations may be identified as “useless” and deleted from the write cache 302 when the cache detects that the effect of the write operation will be nullified by a subsequent write operation to the same memory location. When checking for a cache hit, read cache 202 will also determine whether the data values from the requested memory location are in write cache 302 and, if so, will obtain the requested memory location data values from the write cache.

As both read cache 202 and write cache 302 can initiate operations on memory cell array 102, selection circuit 109 may implement a conflict resolution scheme. For example, selection circuit 109 may implement a turn-based scheme in which each cache is allowed a limited number of accesses before the other cache is given an opportunity to access the memory cell array. Alternatively, the selection circuit 109 may always grant priority access to the write cache 302.

FIG. 5 shows an architecture for a memory device 400 having a low power mode. Note the reversal of cache 202 and ECC decoder 114. When arranged as shown, the operations of cache 202 do not impose any additional burden on ECC decoder 114 over the baseline device 100 (FIG. 2). Relative to memory device 300, the architecture of memory device 400 may reduce power consumption at the expense of requiring a somewhat larger cache memory to store the redundancy information in the code words.

The design of cache 202 may further contribute to a reduction of power consumption in a number of situations. For example, certain cache designs or certain applications of the memory device may provide a very high cache hit rate, and this hit rate may reduce the number of operations performed on memory cell array 102. Such a reduction in the number of operations on the memory cell array may be beneficial if the power required to perform a read operation on array 102 exceeds the power required to retrieve information from the cache. As another example, certain memory cell array architectures may require proportionately less power to perform a read operation when multiple read operations are combined. Cache 202 may perform read operations in blocks and, thus, reduce power consumption. In a similar manner, power may also be conserved by waiting until the write cache is full before initiating actual write operations on the actual memory array.

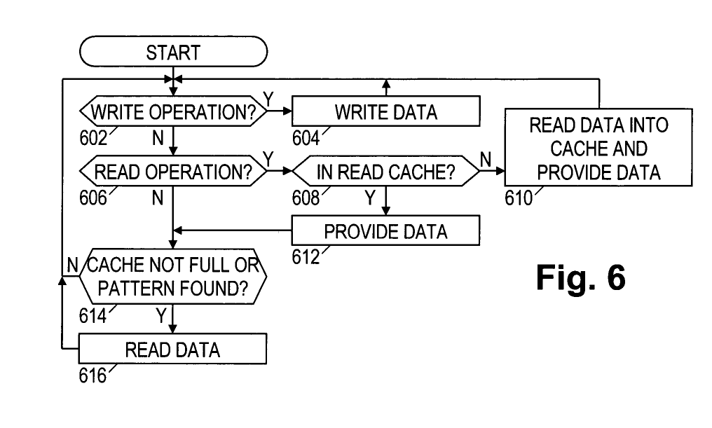

FIG. 6 shows an exemplary flow diagram illustrating the operation of certain integrated memory device embodiments. Beginning in state 602, the controller of cache 202 may evaluate the read/write signal or other indicators to determine whether a write operation is being performed. If a write operation is being performed, the controller enters state 604 to allow the write operation to proceed. Thereafter, control returns to state 602.

Absent a write operation, control transitions to state 606 in which the controller of cache 202 may evaluate the read/write signal or other indicators to determine whether a (external) read operation is being performed. If a read operation is being performed, then in state 608 the controller determines whether the requested memory location data values are contained within the cache memory. If the data is absent from the cache, then in state 610 the requested data is retrieved from the memory array and provided as a data signal in response to the read operation. The data may also be cached along with data from nearby addresses. Control thereafter returns to state 602. Otherwise, if the read operation is requesting data contained in the cache, then in state 612, cache 202 provides the requested data as a data signal in response to the read operation.

From either state 606 or state 612, cache 202 may transition to state 614. In state 614 cache 202 determines whether an update to the cache memory is desirable. An update may be desirable if, e.g., the cache is not full or the caching algorithm determines that data from a newly predicted memory location needs to be read into the cache. If an update is desirable, then in state 616 a read operation is performed on the memory cell array to retrieve new data for cache 202. Afterwards, or if an update is undesirable, control returns to state 602.

Numerous variations to the embodiments described above are contemplated and intended to be within the scope of the appended claims. For example, the terms row and column may be exchanged throughout the discussion above. Each row and/or column may employ multiple row/column lines to provide access to selected memory cells. The encoder and decoder for ECC codes may be augmented or replaced with encryption encoders/decoders, or omitted entirely from certain embodiments. Multiple read caches may be employed, with each cache operating on a segment of the memory array, or alternatively, with each cache implementing a different caching algorithm (e.g., one cache may be operating in a read-ahead mode, while another cache operates based on a statistical jump profile). Further, the above disclosed embodiments may be applied to multiport memories and may additionally or alternatively be applied to memories having volatile or nonvolatile memory cell arrays. In addition, various caching algorithms known to one of ordinary skill in the art can be implemented with embodiments of the present invention.

1. An integrated circuit device that comprises:
a memory array integrated on a substrate, wherein the memory array stores data in encoded form;
a decoder integrated on said substrate, coupled to the memory array and configured to decode data retrieved from the memory array; and
a cache integrated on said substrate, wherein the cache is configured to retrieve data stored in the memory array in anticipation of a request for said data.

2. The device of claim 1, wherein the decoder is coupled between the memory array and the cache, and wherein the cache stores decoded data.

3. The device of claim 1, wherein the cache is coupled between the memory array and the decoder, and wherein the cache stores encoded data.

4. The device of claim 1, wherein the encoded form is in a set consisting of error detection codes, error correction codes, and encryption codes.

5. The device of claim 1, further comprising:
a selection circuit coupled to the memory array to select a set of one or more memory cells in response to an address value; and
a sense circuit coupled to the memory array to sense data stored in the selected set of memory cells,
wherein the cache is configured to receive a read operation comprising an address value, and is further configured to provide the address value to the selection circuit if the cache does not have a copy of data stored in the corresponding set of memory cells.

6. The device of claim 5, further comprising:
wherein the cache is further configured to determine a set of one or more predicted address values and to provide the set of predicted address values to the selection circuit.

7. The device of claim 1, wherein the memory array comprises memory cells of a first information storage technology, and wherein the cache comprises memory cells of a second, different information storage technology.

8. The device of claim 7, wherein memory cells of the first information storage technology orient magnetic fields to store information.

9. The device of claim 8, wherein memory cells of the second information storage technology employ bi-stable circuits to store information.

10. A method of providing access to stored data, the method comprising:
receiving an address value at a cache integrated on a substrate;
retrieving encoded data associated with the address value from a memory cell array integrated on said substrate if the cache does not possess data associated with the address value;
decoding the encoded data; and
providing decoded data as a response to receiving said address value.

11. The method of claim 10, wherein said retrieving comprises:
retrieving encoded data associated with a block of address values containing the received address value if the cache does not possess data associated with the received address value.

12. The method of claim 11, wherein said retrieving further comprises:
storing the retrieved encoded data in the cache.

13. The method of claim 11, wherein said retrieving further comprises:
storing decoded data in the cache.

14. The method of claim 10, further comprising:
retrieving encoded data associated with a subsequent block of address values if the cache does not possess data associated with the subsequent block of address values.

15. The method of claim 14, wherein the subsequent block of address values numerically immediately follows the block of address values containing the received address value.

16. The method of claim 14, wherein the subsequent block of address values statistically follows the block of address values containing the received address value, and wherein the method further comprises:
maintaining for each block of address values a corresponding statistics-gathering field to predict for each block a subsequent block of address values.

17. The method of claim 10, further comprising:
retrieving encoded data associated with multiple subsequent blocks of address values.

18. The method of claim 17, wherein at least one of said multiple subsequent blocks immediately follows in numerical order the block of address values containing the received address value, and wherein at least one of said multiple subsequent blocks statistically follows the block of address values containing the received address value.

19. A digital device comprising:
an assisted memory device having a cache integrated on the same substrate; and
a processor coupled to the assisted memory device and configured to operate on information stored in the assisted memory device.

20. The device of claim 19, wherein the information comprises software instructions for execution by the processor, and wherein the information further comprises data to be operated on in accordance with the software instructions.

21. The device of claim 19, wherein the cache maintains statistics-gathering fields associated with blocks of addresses in a memory cell array of the integrated memory device, and wherein the cache employs the fields to anticipate subsequent memory accesses by the processor.

22. The device of claim 19, wherein the cache comprises a memory cells of a different memory technology than a primary memory cell array of the integrated memory device.
